(19) United States
(12) Patent Application Publication
(10) Pub. No.: US 2025/0140735 A1
(43) Pub. Date: May 1, 2025

(54) DIRECT COPPER WIRE BONDING ON NANOTWIN COPPER STRUCTURES

(71) Applicant: TEXAS INSTRUMENTS INCORPORATED, Dallas, TX (US)

(72) Inventors: Jomari AUSTRIA, Malabon City (PH); Ray Fredric DE ASIS, Mabalacat (PH); Jeffrey Salvacion SOLAS, Iloilo City (PH)

(21) Appl. No.: 18/498,126

(22) Filed: Oct. 31, 2023

(51) Int. Cl. H01L 23/00

(52) U.S. Cl. CPC H01L 24/48; H01L 24/05; H01L 24/08; H01L 24/85; H01L 2224/04042; H01L 2224/05005; H01L 2224/08245; H01L 2224/48175; H01L 2224/48491; H01L 2224/48847; H01L 2224/85897

(57) ABSTRACT

A package comprises a semiconductor die including a device side having circuitry formed therein. The package includes a metal member coupled to the device side and a nanotwin copper member having a bottom surface coupled to the metal member, the nanotwin copper member comprising a twin boundary separating a first region having a first grain structure from a second region having a second grain structure. The package also comprises a wire bond coupled directly to a top surface of the nanotwin copper member, the wire bond contacting multiple regions of the nanotwin copper member. The package also comprises a mold compound covering the die, the metal member, the nanotwin copper member, and the wire bond.

### BACKGROUND

Semiconductor wafers are circular pieces of semiconductor material, such as silicon, that are used to manufacture semiconductor chips. Generally, complex manufacturing processes are used to form numerous integrated circuits on a single wafer. The formation of such circuits on a wafer is called fabrication. After wafer fabrication, the wafer is cut into multiple pieces, called semiconductor dies, with each die containing one of the circuits. The cutting, or sawing, of the wafer into individual dies is called singulation. Dies are then coupled to a lead frame and are covered by a mold compound, which is subsequently sawn to produce a package.

### SUMMARY

A package comprises a semiconductor die including a device side having circuitry formed therein. The package includes a metal member coupled to the device side and a nanotwin copper member having a bottom surface coupled to the metal member, the nanotwin copper member comprising a twin boundary separating a first region having a first grain structure from a second region having a second grain structure. The package also comprises a wire bond coupled directly to a top surface of the nanotwin copper member, the wire bond contacting multiple regions of the nanotwin copper member. The package also comprises a mold compound covering the die, the metal member, the nanotwin copper member, and the wire bond.

A method for manufacturing a package comprises sputtering a seed layer above a metal member, the metal member coupled to a semiconductor die and using photolithography to pattern a photoresist having a cavity above the metal member. The method also comprises forming a nanotwin copper member in the cavity, the nanotwin copper member comprising a twin boundary separating a first region having a first grain structure from a second region having a second grain structure. The method also comprises forming a wire bond on a top surface of the nanotwin copper member using a wire bonder. The method includes covering the semiconductor die and the nanotwin copper member with a mold compound.

### BRIEF DESCRIPTION OF THE DRAWINGS

FIG. 1A is a profile, cross-sectional view of a package including direct copper wire bonding on a nanotwin copper structure, in accordance with various examples.

FIG. 1B is a top-down view of a package including direct copper wire bonding on a nanotwin copper structure, in accordance with various examples.

FIG. 1C is a perspective view of a package including direct copper wire bonding on a nanotwin copper structure, in accordance with various examples.

FIG. 2 is a profile, cross-sectional view of a nanotwin copper structure coupled to a wire bond, in accordance with various examples.

FIG. 3 is a flow diagram of a method for manufacturing a package including direct copper wire bonding on a nanotwin copper structure, in accordance with various examples.

FIGS. 4A1-4H3 are a process flow for manufacturing a package including direct copper wire bonding on a nanotwin copper structure, in accordance with various examples.

FIG. 5A is a profile, cross-sectional view of a wire bond directly coupled to a polycrystalline copper structure.

FIG. 5B is a profile, cross-sectional view of a wire bond directly coupled to a nanotwin copper structure, in accordance with various examples.

FIG. 6 is a block diagram of an electronic device containing a package having a wire bond directly coupled to a nanotwin copper structure, in accordance with various examples.

### DETAILED DESCRIPTION

Packages often contain bond wires, which connect metal members on the device side (i.e., the circuitry side) of a semiconductor die to various structures within the package, such as conductive terminals (e.g., package leads). In this way, the bond wires provide power and/or data signals between the die and the conductive terminals of the package. When forming bonds on the metal members of the die, corrosion or pad oxidation and adhesion can present challenges. A metal stack of nickel and palladium, deposited on the top surface of these metal members of the die, has been useful to mitigate electromigration and to facilitate adhesion to wire bonds. Palladium, however, is expensive, and removing the nickel and palladium is not practical, as the underlying copper of the metal member of the die is of a polycrystalline structure that does not bond well to other copper structures, such as wire bonds. This poor bondability between copper wire bonds and copper metal members is due to a variety of factors, such as corrosion and poor diffusibility of copper in polycrystalline copper applications. It is common to achieve bond areas of less than 60% in copper-to-polycrystalline copper bonding applications.

This disclosure describes various examples of packages in which copper wire bonds are formed directly on nanotwin copper members of the package, such as nanotwin copper members formed on the semiconductor die within the package. Nanotwin copper members include horizontally-oriented twin boundaries that separate multiple regions of a copper member from each other, with each of the multiple regions having a different grain structure. These nanotwin copper members are significantly more amenable to direct copper-to-copper bonding, relative to polycrystalline copper structures. Direct copper-to-nanotwin copper bonds eliminate the need for nickel and palladium plating while improving diffusibility. It is common to achieve bond areas of greater than 80% in copper-to-nanotwin copper bonding applications. In examples, a package comprises a semiconductor die including a device side having circuitry formed therein. The package includes a metal member coupled to the device side, with the metal member in vertical alignment with circuitry on the device side. The package also includes a nanotwin copper member having a bottom surface coupled to the metal member, with the nanotwin copper member comprising a twin boundary separating a first region having a first grain structure from a second region having a second grain structure. The twin boundary is horizontally oriented and is approximately parallel with a horizontal plane in which the semiconductor die lies. The package also includes a wire bond coupled directly to the top surface of the nanotwin copper member. The package also comprises a mold compound covering the die, the metal member, the nanotwin copper member, and the wire bond.

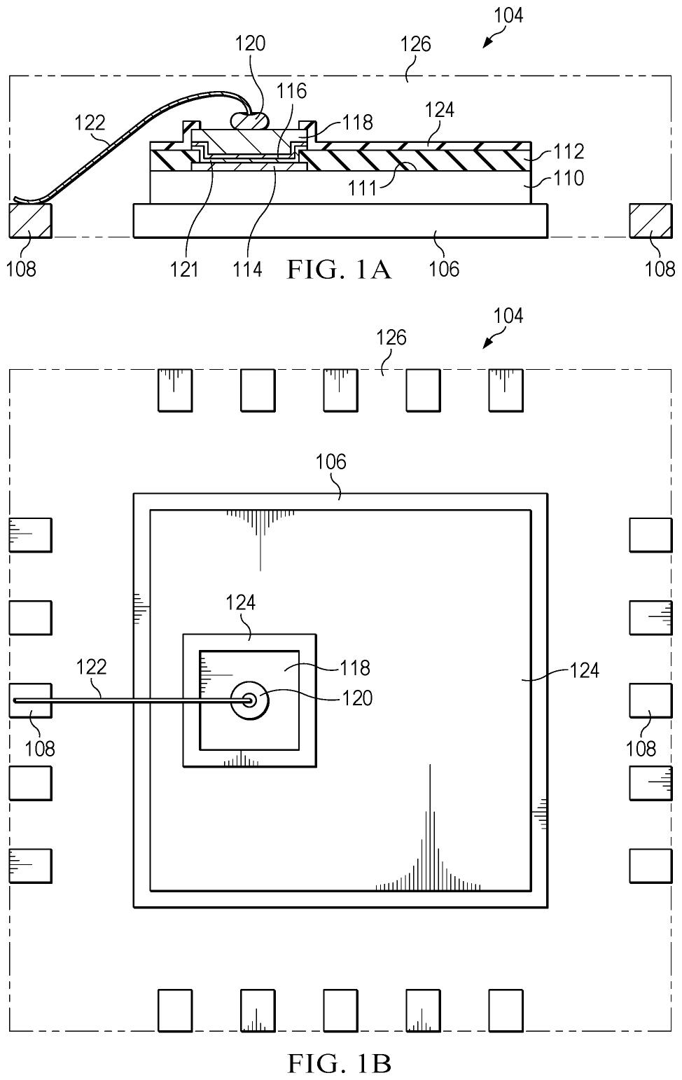

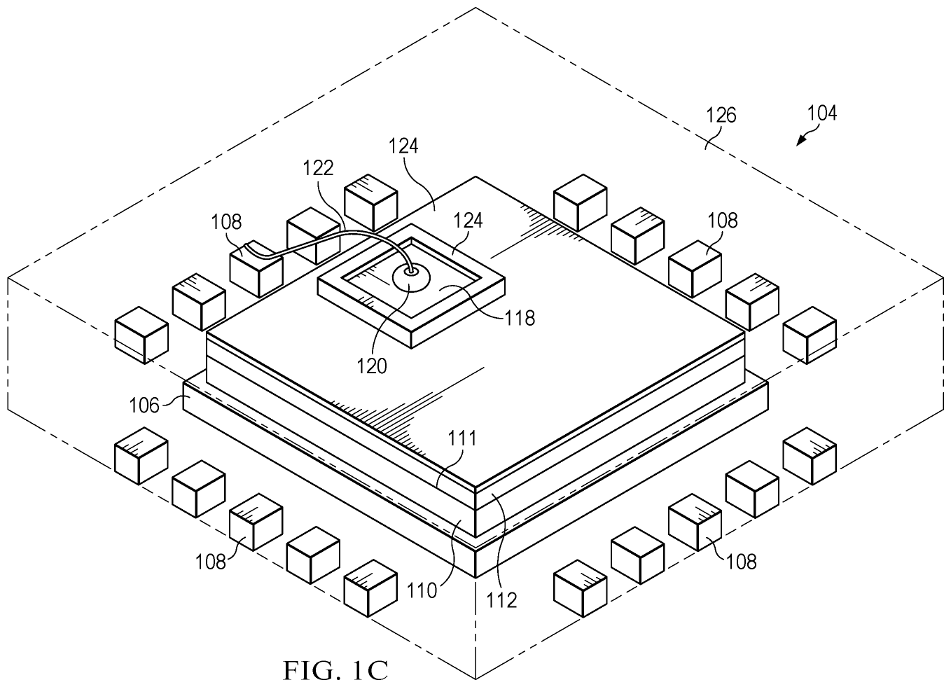

FIG. 1A is a profile, cross-sectional view of a package 104 including direct copper wire bonding on a nanotwin copper structure, in accordance with various examples. In particular, the package 104 includes a die pad 106 and conductive terminals 108. Although the package 104 is depicted as a quad flat no lead (QFN) package, the package 104 may be any suitable type of package in which copper bond pads are coupled to other copper components, such as wire bonds. The package 104 includes a semiconductor die 110 coupled to the die pad 106, for example using a die attach material. The semiconductor die 110 includes a device side 111 in which circuitry is formed. A metal member 114 is coupled to the device side 111—for example, to metallization on the device side 111 that couples to circuitry of the semiconductor die 110. A sputtered barrier layer 121 (e.g., titanium-tungsten, titanium) contacts the metal member 114. A sputtered seed layer 116 contacts the barrier layer 121. A copper member 118 contacts the seed layer 116. As described in greater detail below, the copper member 118 is a nanotwin copper member and excludes polycrystalline copper. An insulative layer 112, such as a passivation layer, contacts the device side 111 and the metal member 114. An insulative layer 124, such as a polyimide layer, may contact the insulative layer 112 and the copper member 118. A wire bond 120 (e.g., a ball bond, such as a copper ball bond) is bonded to the copper member 118. A bond wire 122 is coupled to the wire bond 120 and to one of the conductive terminals 108. A mold compound 126 covers the various structures described above, as shown. The conductive terminals 108 are exposed to an exterior of the mold compound 126, as shown. The stack including the metal member 114, the barrier layer 121, the seed layer 116, and the copper member 118 does not include nickel or palladium. FIG. 1B is a top-down view of the structure of FIG. 1A, in accordance with various examples. FIG. 1C is a perspective view of the structure of FIG. 1A, in accordance with various examples.

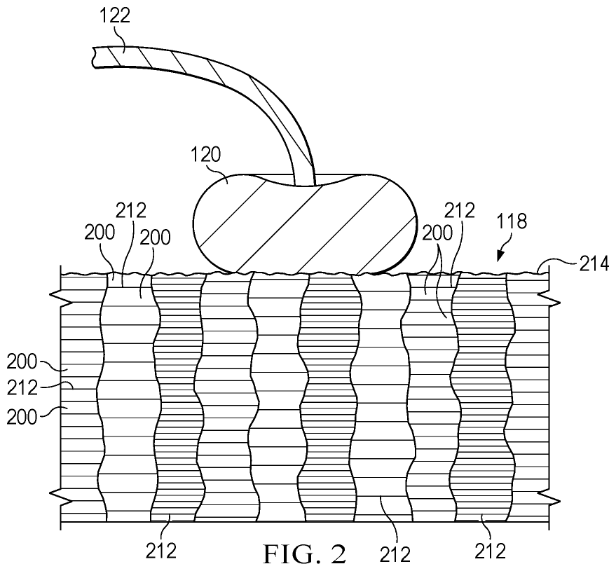

FIG. 2 is a profile, cross-sectional view of a nanotwin copper structure coupled to a wire bond, in accordance with various examples. More specifically, FIG. 2 shows a close-up view of the copper member 118 coupled to the wire bond 120. The copper member 118 is a nanotwin copper structure (i.e., nanocrystalline copper with nanotwins). A nanotwin copper structure includes nanoscale twin boundaries separating the copper grains of the structure. Twin boundaries are planar defects that separate two regions of a crystal that have a very similar, or mirror, image relationship to each other. In nanotwin copper, these twin boundaries are highly dense and closely spaced. In FIG. 2, the copper member 118 includes regions 200 separated by respective twin boundaries 212. The twin boundaries 212 are horizontally oriented, as shown, and are approximately parallel to the horizontal plane in which the semiconductor die 110 (FIG. 1A) lies. As used herein, approximately parallel means parallel or within plus or minus 10 degrees from parallel. Each region 200 has a different grain structure, with the twin boundaries 212 separating respective pairs of regions 200 having mirror-image grain structures.

The wire bond 120 is bonded to a surface 214 of the copper member 118. The wire bond 120 is bonded to two or more regions 200 of the copper member 118. Relative to polycrystalline copper, the nanotwin copper of the copper member 118 forms superior direct bonds to other copper structures (e.g., copper ball bonds) by improving diffusibility between the copper member 118 and the wire bond 120. This superior diffusibility is possible because nanotwin copper has a (111) plane orientation, which has the highest diffusivity amongst all crystal orientations. Direct copper-to-nanotwin copper bonds eliminate the need for nickel and palladium plating while improving diffusibility.

The copper member 118 has a thickness ranging from 5 microns to 13 microns. A thickness below this range is disadvantageous because damage to the metal member 114 occurs during the wirebonding process resulting in cracking, and a thickness above this range is disadvantageous because it increases the electroplating cycle time and causes high stress due to its weight on top of metal member 114.

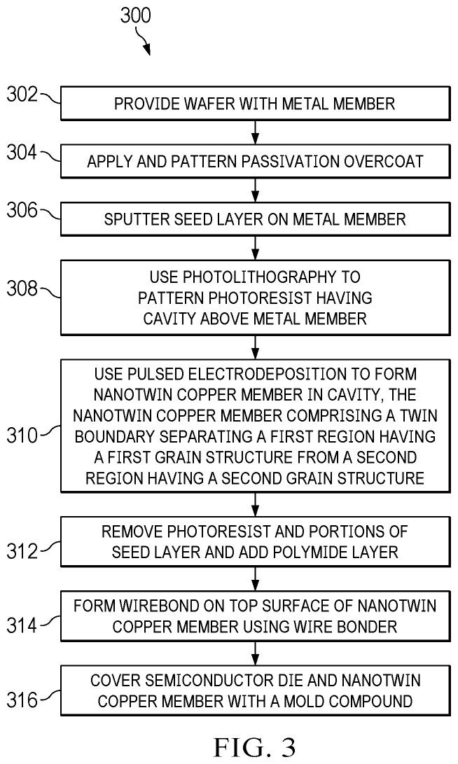

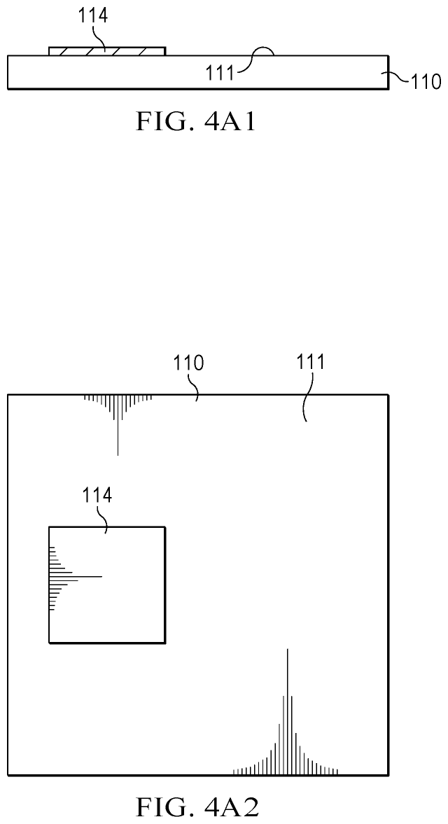

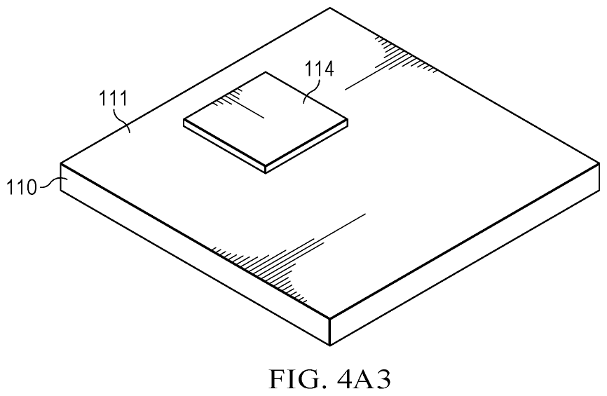

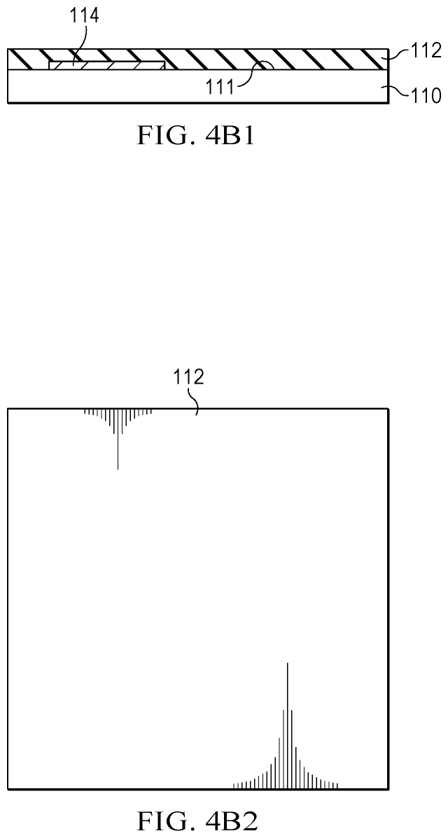

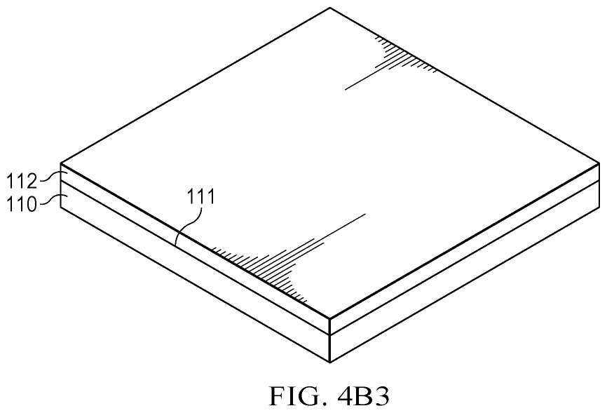

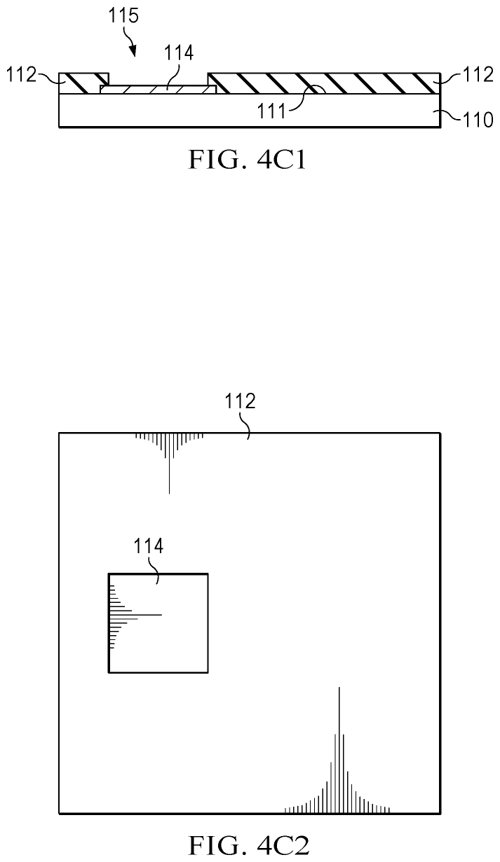

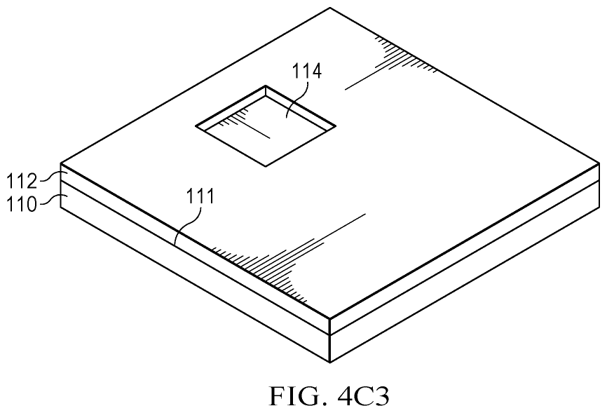

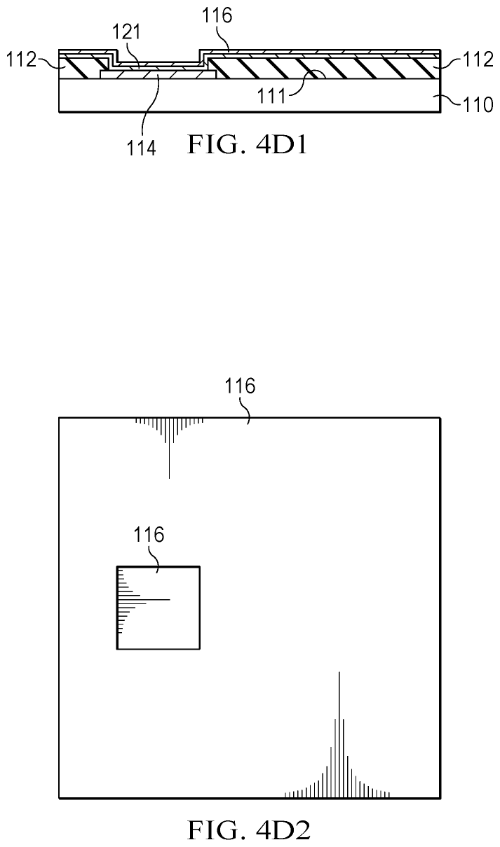

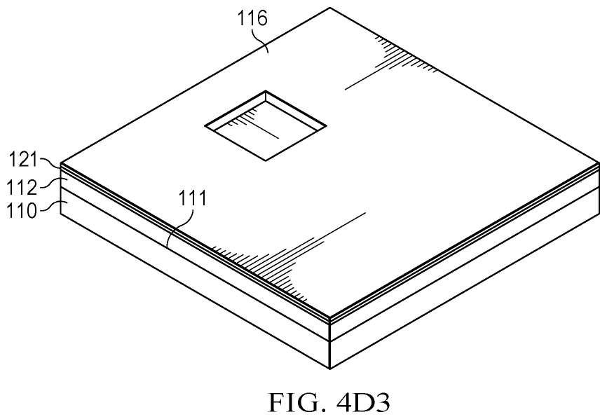

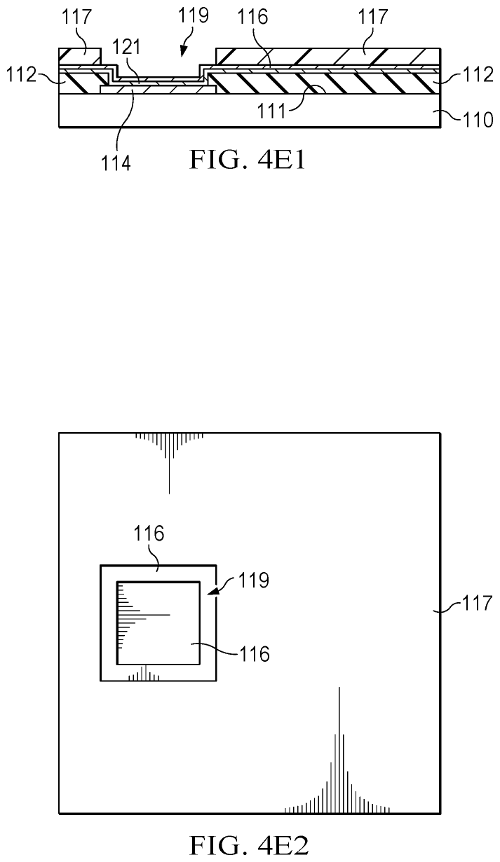

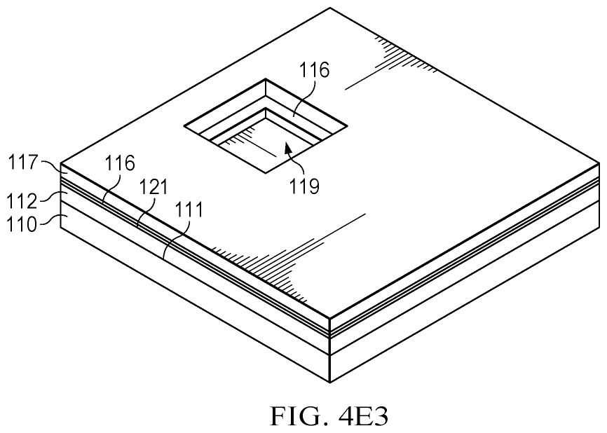

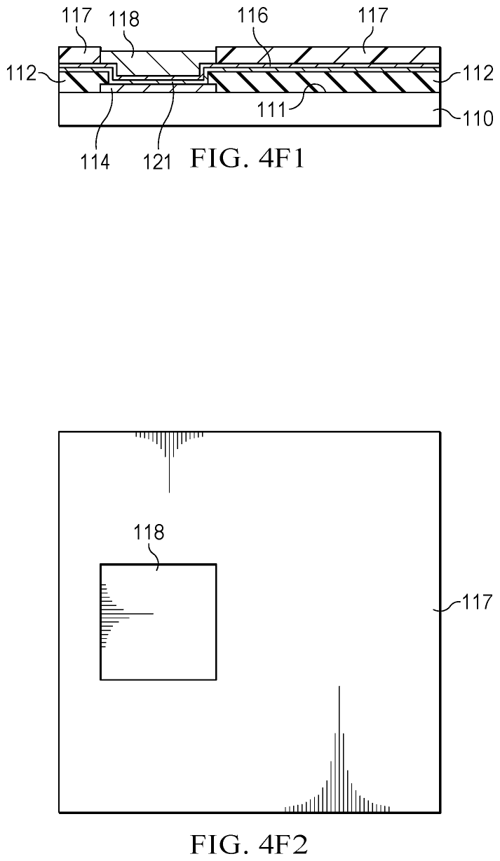

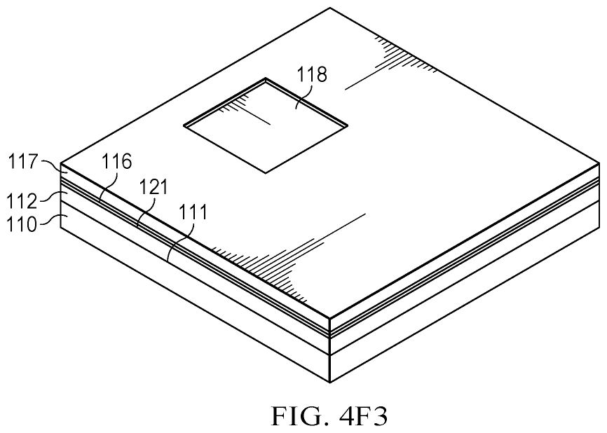

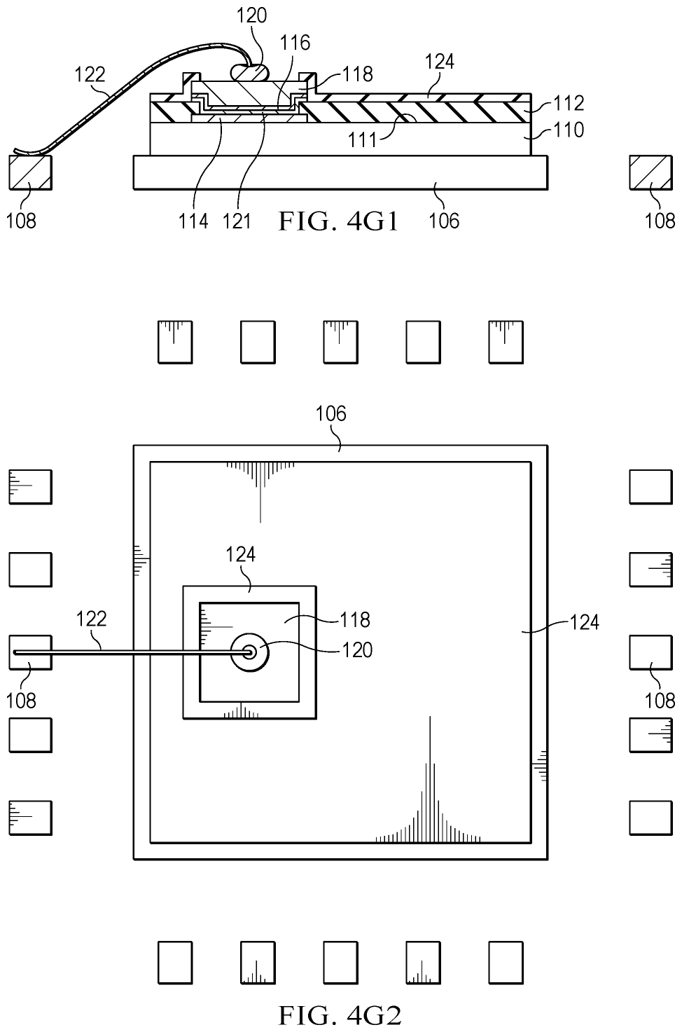

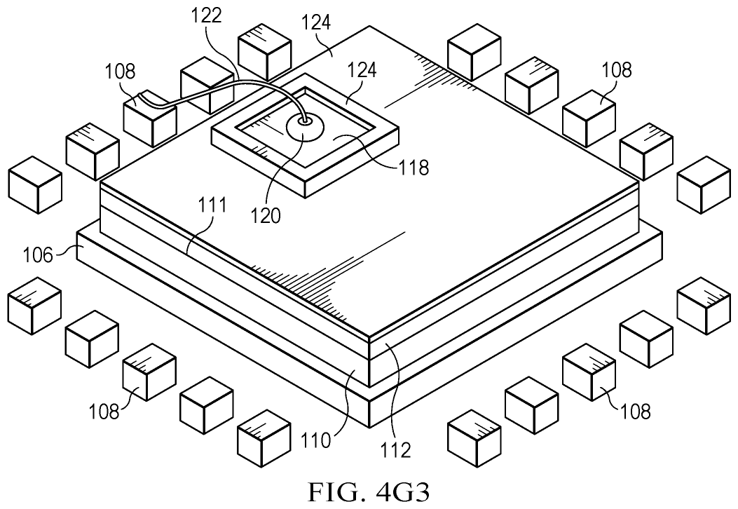

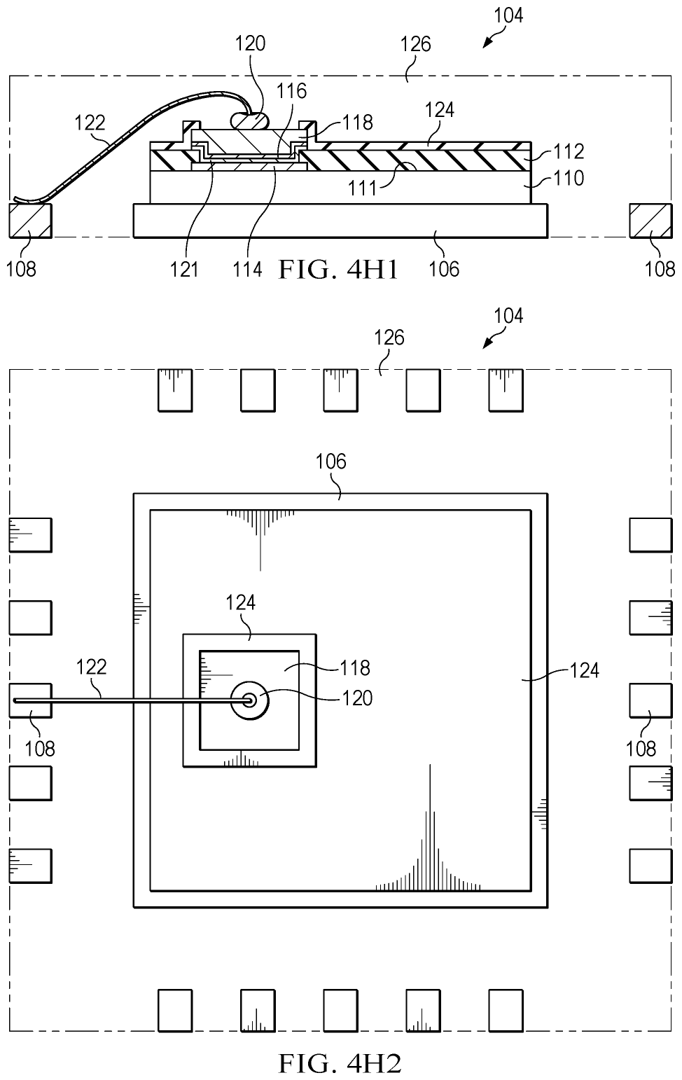

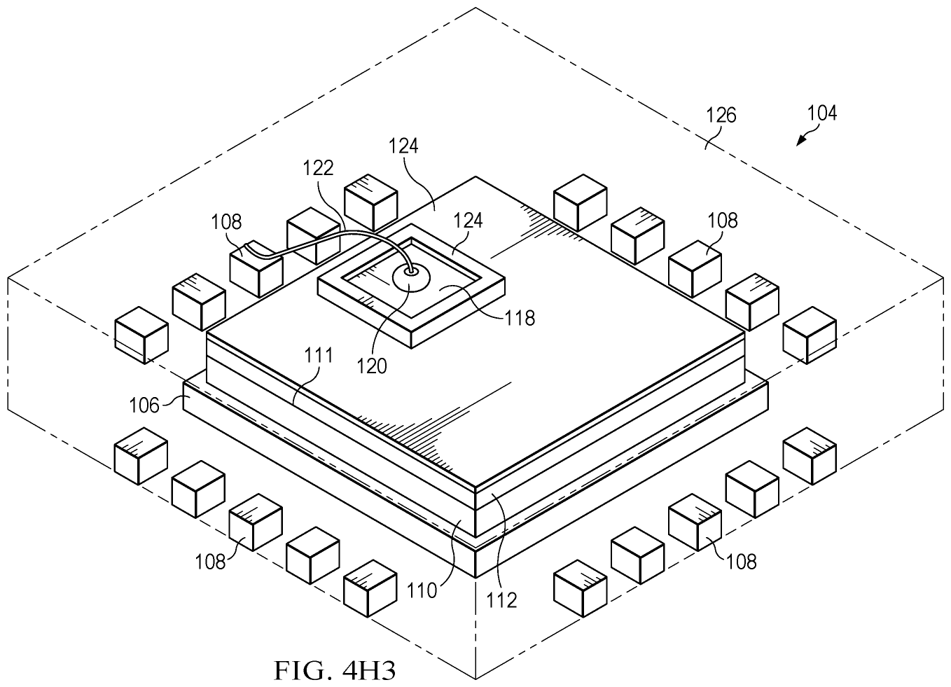

FIG. 3 is a flow diagram of a method for manufacturing a package including direct copper wire bonding on a nanotwin copper structure, in accordance with various examples. FIGS. 4A1-4H3 are a process flow for manufacturing a package including direct copper wire bonding on a nanotwin copper structure, in accordance with various examples. Accordingly, FIGS. 3 and 4A1-4H3 are now described in parallel.

The method 300 begins with providing a semiconductor wafer with a metal member positioned on a device side of the wafer (302). FIG. 4A1 is a profile, cross-sectional view of a semiconductor wafer 110 having a metal member 114 positioned on the device side 111 of the wafer 110. The device side 111 is the side of the wafer 110 in which circuitry is formed. Although the numeral 110 is used herein to denote a semiconductor die, for ease of explanation, the numeral 110 may also be used to denote a semiconductor wafer that is subsequently singulated to produce the semiconductor die 110. FIG. 4A2 is a top-down view of the structure of FIG. 4A1, in accordance with various examples. FIG. 4A3 is a perspective view of the structure of FIG. 4A1, in accordance with various examples.

The method 300 includes applying and patterning a passivation overcoat (304). FIG. 4B1 is a profile, cross-sectional view of the structure of FIG. 4A1, except with the addition of the insulative layer 112 (e.g., a passivation overcoat layer). The insulative layer 112 contacts the metal member 114 and the device side 111, as shown. FIG. 4B2 is a top-down view of the structure of FIG. 4B1, in accordance with various examples. FIG. 4B3 is a perspective view of the structure of FIG. 4B1, in accordance with various examples. FIG. 4C1 shows the structure of FIG. 4B1, except that an opening 115 is formed in the insulative layer 112 above the metal member 114 (e.g., using photolithography techniques). FIG. 4C2 is a top-down view of the structure of FIG. 4C1, in accordance with various examples. FIG. 4C3 is a perspective view of the structure of FIG. 4C2, in accordance with various examples.

The method 300 includes sputtering a barrier layer on the metal member and a seed layer on the barrier layer (306). FIG. 4D1 shows the structure of FIG. 4C1, except that the barrier layer 121 is applied to the insulative layer 112 and the metal member 114, and the seed layer 116 is applied to the barrier layer 121. The barrier layer 121 comprises titanium or a titanium-tungsten alloy, and the seed layer 116 is a copper seed layer. FIG. 4D2 is a top-down view of the structure of FIG. 4D1, in accordance with various examples. FIG. 4D3 is a perspective view of the structure of FIG. 4D1, in accordance with various examples.

The method 300 includes using photolithography to pattern a photoresist having a cavity above the metal member (308). FIG. 4E1 is a profile, cross-sectional view of the structure of FIG. 4D1, except that a photoresist layer 117 is applied to the seed layer 116, and photolithography techniques are used to form a cavity 119 above the metal member 114, as shown. FIG. 4E2 is a top-down view of the structure of FIG. 4E1, in accordance with various examples. FIG. 4E3 is a perspective view of the structure of FIG. 4E1, in accordance with various examples.

The method 300 includes using pulsed electrodeposition to form a nanotwin copper member in the cavity, with the nanotwin copper member comprising a twin boundary separating a first region having a first grain structure from a second region having a second grain structure (310). FIG. 4F1 is a profile, cross-sectional view of the structure of FIG. 4E1, except that the copper member 118 (i.e., a nanotwin copper member) is formed in the cavity 119 by pulsed electrodeposition. The copper member 118 has the physical features attributed herein to nanotwin copper structures, such as those described with reference to FIG. 2. FIG. 4F2 is a top-down view of the structure of FIG. 4F1, in accordance with various examples. FIG. 4F3 is a perspective view of the structure of FIG. 4F2, in accordance with various examples. In some examples, techniques other than electrodeposition can be useful, such as a nanotwin copper electroplating bath. Furthermore, the aforementioned titanium barrier layer 121 orients the sputtered copper seed layer 116 to a (111) plane orientation, and during electroplating, this (111) plane orientation acts as a precursor material to form the nanotwin copper and eliminates the need for pulsed electrodeposition.

The method 300 includes removing the photoresist and portions of the barrier and seed layers, and optionally applying a polyimide layer (312). The method 300 also includes forming a wire bond on the top surface of the nanotwin copper member after the structure of FIG. 4F1 is coupled to a die pad using a die attach material (314). FIG. 4G1 is a profile, cross-sectional view of the structure of FIG. 4F1, except that the photoresist layer 117 is stripped, the portions of the seed layer 116 that are not directly beneath the copper member 118 are etched away, and the insulative layer 124 (e.g., a polyimide layer) is applied to contact the insulative layer 112 and the copper member 118, as shown. FIG. 4G1 also depicts the bonding of the wire bond 120 to the top surface of the copper member 118 (i.e., the nanotwin copper member), with the bond wire 122 bonded to one of the conductive terminals 108, such as by a stitch bond. FIG. 4G2 is a top-down view of the structure of FIG. 4G1, in accordance with various examples. FIG. 4G3 is a perspective view of the structure of FIG. 4G1, in accordance with various examples.

Forming the wire bond 120 includes using a wire bonding temperature ranging between 90 degrees Celsius and 120 degrees Celsius, with a temperature below this range being disadvantageous because no bond can be formed since low temperature bonding is still driven by diffusion which is accelerated by temperature, and with a temperature above this range being disadvantageous because oxidation of the pad can occur during the wire bonding process and inhibit good bond formation. During a first wire bonding time segment, a wire bonder is used to apply a first force on the top surface of the copper member 118 for a first length of time, with the first force ranging between 15 grams and 25 grams, and the first length of time ranging between 1 millisecond and 5 milliseconds. During a second wire bonding time segment after the first wire bonding time segment, the wire bonder is used to apply a second force on the top surface of the copper member 118 while scrubbing the top surface of the copper member 118, with the second force ranging between 15 grams and 25 grams. During a third wire bonding time segment after the second wire bonding time segment, the wire bonder is used to apply a third force on the top surface of the copper member 118 for a second length of time, with the third force ranging between 45 grams and 55 grams, and with the second length of time ranging between 15 milliseconds and 25 milliseconds. The ultrasonic energy applied during the third wire bonding time segment is greater than an ultrasonic energy applied during the second wire bonding time segment. The ultrasonic energy applied during the second wire bonding time segment is greater than an ultrasonic energy applied during the first wire bonding time segment.

The method 300 includes covering the semiconductor die and nanotwin copper member with a mold compound (316). FIG. 4H1 is a profile, cross-sectional view of the structure of FIG. 4G1, except that a mold compound 126 is applied to cover the various structures shown in FIG. 4G1. The conductive terminals 108 are exposed to an exterior of the mold compound 126. FIG. 4H2 is a top-down view of the structure of FIG. 4H1, in accordance with various examples. FIG. 4H3 is a perspective view of the structure of FIG. 4H1, in accordance with various examples.

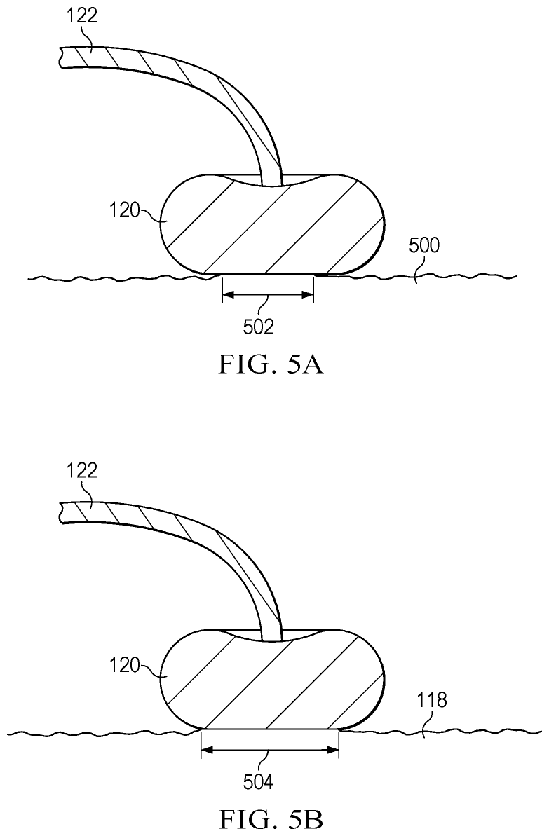

FIG. 5A is a profile, cross-sectional view of the wire bond 120 directly coupled to a polycrystalline copper structure 500. As explained, polycrystalline copper is inferior to nanotwin copper in terms of diffusibility and, thus, bondability to copper structures, such as wire bonds. Thus, the wire bond 120 forms a bond with the polycrystalline copper structure 500 that has a bond area 502 of only 56%. This means that of the surface area of the wire bond 120 that could bond to the polycrystalline copper structure 500, only 56% of that surface area successfully bonds to the polycrystalline copper structure 500. In contrast, FIG. 5B is a profile, cross-sectional view of the wire bond 120 directly coupled to the copper member 118 (i.e., the nanotwin copper structure), in accordance with various examples. The wire bond 120 has a bond area 504 of 83% with the copper member 118, because the copper member 118 is a nanotwin copper structure.

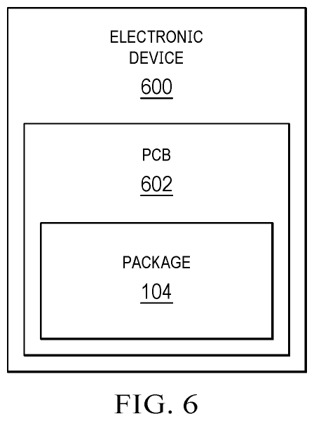

FIG. 6 is a block diagram of an electronic device 600 containing a package having a wire bond directly coupled to a nanotwin copper structure, in accordance with various examples. The electronic device 600 includes a printed circuit board (PCB) 602. The package 104 may be coupled to the PCB 602. The electronic device 600 may include, for example, a personal computer, a laptop, a desktop, a notebook, a tablet, a smartphone, an appliance (e.g., refrigerator, television, audio player, video player, video recorder, lighting device, etc.), an automobile, an aircraft, a spacecraft, etc.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

In this description, unless otherwise stated, “about,” “approximately” or “substantially” preceding a parameter means being within +/−10 percent of that parameter. Modifications are possible in the described examples, and other examples are possible within the scope of the claims.

What is claimed is:

1. A package, comprising:
a semiconductor die including a device side having circuitry formed therein;
a metal member coupled to the device side;
a nanotwin copper member having a bottom surface coupled to the metal member, the nanotwin copper member comprising a twin boundary separating a first region having a first grain structure from a second region having a second grain structure;
a wire bond coupled directly to a top surface of the nanotwin copper member, the wire bond contacting multiple regions of the nanotwin copper member; and
a mold compound covering the die, the metal member, the nanotwin copper member, and the wire bond.

2. The package of claim 1, wherein the package does not include a nickel layer in a same metal stack as the nanotwin copper member.

3. The package of claim 1, wherein the package does not include a palladium layer in a same metal stack as the nanotwin copper member.

4. The package of claim 1, wherein the nanotwin copper member excludes polycrystalline copper.

5. The package of claim 1, wherein at least 80% of a bottom surface of the wire bond is bonded to the nanotwin copper member, the bottom surface of the wire bond facing the nanotwin copper member.

6. The package of claim 1, wherein the twin boundary is oriented approximately parallel to a horizontal plane in which the semiconductor die lies.

7. The package of claim 1, wherein the nanotwin copper member has a minimum thickness of 5 microns and a maximum thickness of 13 microns.

8. A package, comprising:
a semiconductor die including a device side having circuitry formed therein;
a metal member coupled to the device side, the metal member in vertical alignment with the circuitry;
a nanotwin copper member coupled to the metal member, the nanotwin copper member having a minimum thickness of 5 microns and a maximum thickness of 13 microns, the nanotwin copper member comprising a twin boundary oriented approximately parallel to a horizontal plane in which the semiconductor die lies;
a wire bond coupled directly to a surface of the nanotwin copper member; and
a mold compound covering the die, the metal member, the nanotwin copper member, and the wire bond.

9. The package of claim 8, wherein the twin boundary separates a first region having a first grain structure from a second region having a second grain structure.

10. The package of claim 9, wherein the wire bond contacts multiple regions of the nanotwin copper member, each of the multiple regions having differing grain structures.

11. The package of claim 8, wherein the package does not include a nickel layer in a same metal stack as the nanotwin copper member.

12. The package of claim 8, wherein the package does not include a palladium layer in a same metal stack as the nanotwin copper member.

13. The package of claim 8, wherein the nanotwin copper member excludes polycrystalline copper.

14. The package of claim 8, wherein at least 80% of a bottom surface of the wire bond is bonded to the nanotwin copper member, the bottom surface of the wire bond facing the nanotwin copper member.

15. A method for manufacturing a package, comprising:
sputtering a seed layer above a metal member, the metal member coupled to a semiconductor die;
using photolithography to pattern a photoresist having a cavity above the metal member;
forming a nanotwin copper member in the cavity, the nanotwin copper member comprising a twin boundary separating a first region having a first grain structure from a second region having a second grain structure;
forming a wire bond on a top surface of the nanotwin copper member using a wire bonder; and
covering the semiconductor die and the nanotwin copper member with a mold compound.

16. The method of claim 15, wherein the package does not include a nickel layer in a same metal stack as the nanotwin copper member.

17. The method of claim 15, wherein the package does not include a palladium layer in a same metal stack as the nanotwin copper member.

18. The method of claim 15, wherein the nanotwin copper member excludes polycrystalline copper.

19. The method of claim 15, wherein at least 80% of a bottom surface of the wire bond is bonded to the nanotwin copper member, the bottom surface of the wire bond facing the nanotwin copper member.

20. The method of claim 15, wherein the twin boundary is oriented approximately parallel to a horizontal plane in which the semiconductor die lies.

21. The method of claim 15, wherein the nanotwin copper member has a minimum thickness of 5 microns and a maximum thickness of 13 microns.

22. The method of claim 15, wherein forming the wire bond includes using a wire bonding temperature ranging between 90 degrees Celsius and 120 degrees Celsius.

23. The method of claim 15, wherein forming the wire bond comprises:
during a first wire bonding segment, using a wire bonder to apply a first force on the top surface of the nanotwin copper member for a first length of time, the first force ranging between 15 grams and 25 grams, and the first length of time ranging between 1 millisecond and 5 milliseconds;
during a second wire bonding segment after the first wire bonding segment, using the wire bonder to apply a second force on the top surface of the nanotwin copper member while scrubbing the top surface of the nanotwin copper member, the second force ranging between 15 grams and 25 grams; and
during a third wire bonding segment after the second wire bonding segment, using the wire bonder to apply a third force on the top surface of the nanotwin copper member for a second length of time, the third force ranging between 45 grams and 55 grams, and the second length of time ranging between 15 milliseconds and 25 milliseconds,
wherein an ultrasonic energy applied during the third wire bonding segment is greater than an ultrasonic energy applied during the second wire bonding segment, and the ultrasonic energy applied during the second wire bonding segment is greater than an ultrasonic energy applied during the first wire bonding segment.

24. The method of claim 15, wherein forming the nanotwin copper member in the cavity comprises using pulsed electrodeposition.
